(19) United States
(12) Patent Application Publication
(10) Pub. No.: US 2008/0173347 A1
(43) Pub. Date: Jul. 24, 2008

(54) Method And Apparatus For A Semiconductor Structure

(75) Inventors: Bastiaan Arie Korevaar, Schenectady, NY (US); James Neil Johnson, Scotia, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/625,841

(22) Filed: Jan. 23, 2007

(51) Int. Cl. H01L 31/036; H01L 31/18

(52) U.S. Cl. 136/255; 257/53; 438/87; 257/E31.045; 257/E31.049

(57) ABSTRACT

One exemplary embodiment is a semiconductor structure, that can include a semiconductor substrate of one conductivity type, having a front surface and a back surface, a first semiconductor layer disposed on the front surface of the semiconductor substrate, a second semiconductor layer disposed on a portion of the back surface of the semiconductor substrate, and a third semiconductor layer disposed on another portion of the back surface of the semiconductor substrate. Each of the second and third semiconductor layers may be compositionally graded through its depth, from substantially intrinsic at an interface with the substrate, to substantially conductive at an opposite side, and have a selected conductivity type obtained by the incorporation of one or more selected dopants.

### CROSS-REFERENCE TO RELATED APPLICATIONS

Non-provisional application no. ______, entitled, “METHOD AND APPARATUS FOR A SEMICONDUCTOR STRUCTURE FORMING AT LEAST ONE VIA”, filed, by Korevaar et al. (Attorney Docket No. 218410-1) and application Ser. No. 11/480,161, entitled, “PHOTOVOLTAIC DEVICE WHICH INCLUDES ALL-BACK-CONTACT CONFIGURATION; AND RELATED PROCESSES”, filed Jun. 30, 2006, for Johnson et al. are incorporated by reference in their entirety.

### FIELD

The embodiments described herein generally relate to one or more solar modules. More specifically, the embodiments relate to one or more solar modules based on at least one semiconductor structure.

### BACKGROUND

There is no doubt that solar energy offers the potential for providing virtually unlimited energy for man, if the solar energy can be made available in a useful form. Perhaps the greatest effort so far has been using the sun's energy to obtain electricity, which can then be utilized through any existing electrical network: on the household, community, or industrial level. A primary approach to generating this electricity from solar radiation has involved direct generation by way of photovoltaic converters. These types of devices rely on the presence of a heterojunction and are well-known in the art. As used in this context, a heterojunction is a semiconductor junction which is composed of layers of dissimilar semiconductor material. As one example, a heterojunction can be formed by contact between a layer or region of one conductivity type with a layer or region of an opposite conductivity, e.g., a “p-n” junction. In addition to solar cells, other devices which utilize the heterojunction include thin film transistors and bipolar transistors.

In general, photovoltaic devices convert radiation, such as solar, incandescent, or fluorescent radiation, into electrical energy. Sunlight is the typical source of radiation for most devices. The conversion to electrical energy is achieved by the well-known photovoltaic effect. According to this phenomenon, radiation striking a photovoltaic device is absorbed by an active region of the device, generating pairs of electrons and holes, which are sometimes collectively referred to as photo-generated charge carriers. The electrons and holes diffuse, and are collected at the contacts by, e.g., the electric field built into the device.

In view of the potential for solar cells to serve as such a reliable form of clean, renewable energy, great efforts have been made to increase their performance. One primary measurement for such performance is the photoelectric conversion efficiency of the device. Conversion efficiency is usually measured as the amount of electrical current generated by the device, as a proportion of the active surface exposed to the light energy. As documented in the literature, extremely small increases in photoelectric conversion efficiency, e.g., 1% or less, represent very significant advances in photovoltaic technology.

The performance of photovoltaic devices depends in large part on the composition and microstructure of each semiconductor layer. For example, defect sites that result from structural imperfections or impurity atoms may reside on the surface or within the bulk of mono-crystalline semiconductor layers. Moreover, poly-crystalline semiconductor materials may contain randomly-oriented grains, with grain boundaries which induce a large number of bulk and surface defect sites.

The presence of various defects of this type can be the source of deleterious effects in the photovoltaic device. For example, many of the charge carriers recombine at the defect sites near the heterojunction, instead of continuing on their intended pathway to one of the collection electrodes. Thus, they become lost as current carriers. Recombination of the charge carriers is one of the chief reasons for decreased photoelectric conversion efficiency.

The negative effects of surface defects can be minimized to some degree by passivation techniques. For example, a layer of a suitable intrinsic (i.e., undoped) amorphous semiconductor material can be formed on the surface of the substrate to occupy any dangling bonds at the surface. The presence of the suitable intrinsic layer decreases the recombination of charge carriers at the substrate surface, and thereby improves the performance of the photovoltaic device.

The use of this type of intrinsic layer is generally described in U.S. Pat. No. 5,213,628 (Noguchi et al.). Noguchi describes a photovoltaic device which includes a mono-crystalline or poly-crystalline semiconductor layer of a selected conductivity type. A substantially intrinsic and substantially amorphous layer of 250 angstroms or less is formed over the substrate. A substantially amorphous layer is formed over the intrinsic layer, having a conductivity opposite that of the substrate, and completing a “semiconductor sandwich structure.” The photovoltaic device is completed by the addition of a light-transparent electrode over the amorphous layer, and a back electrode attached to the underside of the substrate. Another passivation procedure is exposing a surface to an acid, such as hydrogen fluoride, to remove any free radicals, which can be incorporated into a passivation technique.

The photovoltaic devices described in the Noguchi patent appear to considerably minimize the problem of charge carrier recombination in some situations. For example, the presence of the intrinsic layer at selected thicknesses is said to increase the photoelectric conversion efficiency of the device. Moreover, the concept of passivating the surfaces of semiconductor substrates in this manner has been described in a number of references since the issuance of Noguchi et al. Examples include U.S. Pat. No. 5,648,675 (Terada et al.); U.S. Patent Publications 2002/0069911 A1 (Nakamura et al.); 2003/0168660 A1 (Terakawa et al.); and 2005/0062041 A1 (Terakawa et al.).

While the references mentioned above address the recombination problem to some degree, there are some considerable drawbacks remaining.

Generally, an amorphous layer on the front of a photovoltaic device can result in absorption of light, which is thus lost from the cell. Although the thickness of the amorphous layer can be minimized, there still may be a loss of current of about 1 mA/cm². Any light absorbed in the passivation layer can contribute to a leakage current and can be lost. The mechanism for this loss is that charge carriers generated in the amorphous intrinsic layer may cause recombination at the interface with charge carriers generated in the crystalline silicon, thereby increasing losses.

Furthermore, there are other factors which can still decrease the performance of conventional solar cells. As an example, solar cells in the past have often been produced with many of the electrical connections on the front-side of the cell, i.e., the surface receiving incident light. Thus, the front surface of the cell usually included front-side metal grid lines or current collection ribbons, along with associated devices and hardware, such as bus bars and tabs.

The presence of these features on the front-side of a solar cell can be disadvantageous for a number of reasons. For example, the grid lines and tabs detract from the uniformity and overall appearance of the solar cell. Aesthetic features for the solar cells often represent critical quality parameters, e.g., in residential home design. Moreover, the operational performance of the solar cell can be adversely affected by the presence of these front-side features, since they “shade” portions of the incident light which would otherwise be absorbed by the cell.

The various problems associated with front surface features in solar cells have been addressed with some success. As an example, silicon photovoltaic devices with all of the electrical connections on the back side of the cell have been developed. As described in U.S. Pat. No. 5,053,083 (Sinton), the “back side”-type of cell can exhibit increased efficiency—primarily due to the lack of front-side features which block the desired light energy. Moreover, the absence of these features can facilitate other treatments and operations on the front-side of the cell, e.g., texturing applications, as described below.

Nevertheless, the drive to increase photoelectric efficiency continues to be relentless, since efficiency directly affects the economic viability of photovoltaic devices. Thus, improved photovoltaic devices would be very welcome in the art. The devices should minimize the problem of charge-carrier recombination at various interface regions between semiconductor layers. Moreover, the devices should exhibit electrical properties which ensure good photovoltaic performance, e.g., photoelectric conversion efficiency. Furthermore, the devices should be capable of being made efficiently and economically.

The fabrication of the devices should eliminate process steps which would allow the entry of excessive levels of impurities and other defects. Another important requirement for many of these devices is their visual features. Specifically, the solar cell structure should be aesthetically pleasing and stylish when used in certain applications, e.g., architectural designs for homes and other structures.

### SUMMARY

One exemplary embodiment is a semiconductor structure, that can include:

(a) a semiconductor substrate of one conductivity type, having a front surface and a back surface;

(b) a first semiconductor layer disposed on the front surface of the semiconductor substrate;

(c) a second semiconductor layer disposed on a portion of the back surface of the semiconductor substrate, wherein the second semiconductor layer is compositionally graded through its depth, from substantially intrinsic at an interface with the substrate, to substantially conductive at an opposite side, the second semiconductor layer having a selected conductivity type obtained by the incorporation of one or more selected dopants; and

(d) a third semiconductor layer disposed on another portion of the back surface of the semiconductor substrate, and spaced from the second semiconductor layer, wherein the third semiconductor layer is compositionally graded through its depth, from substantially intrinsic at an interface with the substrate, to substantially conductive at an opposite side, the third semiconductor layer having a conductivity type different from that of the second layer, and obtained by the incorporation of one or more selected dopants.

Another exemplary embodiment is a semiconductor structure that can include:

(a) a semiconductor substrate having a front surface and a back surface;

(b) a first semiconductor layer disposed on the front surface of the semiconductor substrate; and

(c) a second semiconductor layer, disposed on at least a portion of the back surface of the semiconductor substrate, and compositionally graded through its depth with one or more selected dopants.

A further exemplary embodiment is a semiconductor structure that may include:

(a) a semiconductor substrate, having a front surface and a back surface wherein the semiconductor substrate includes a diffused region proximate to at least a portion of its back surface; and

(b) a semiconductor layer disposed on another portion of the back surface of the semiconductor substrate, wherein the semiconductor layer is compositionally graded through its depth by the incorporation of one or more selected dopants.

Yet another exemplary embodiment is a solar module, including one or more solar cell devices. At least one of the solar cell devices may include a semiconductor structure described herein.

Still yet another exemplary embodiment is a method for making a photovoltaic device. The method can include:

(I) forming a first semiconductor layer over a front surface of a semiconductor substrate;

(II) forming a second semiconductor layer on a portion of a back surface of the semiconductor substrate, by depositing semiconductor material and a dopant over the back surface portion, while altering the concentration of the dopant, so that the second semiconductor layer becomes compositionally-graded through its depth, from substantially intrinsic at the interface with the back surface of the substrate, to substantially conductive at the opposite side; and

(III) forming a third semiconductor layer on another portion of the back surface of the semiconductor substrate, by depositing semiconductor material and a dopant over the back surface portion, while altering the concentration of the dopant, so that the third semiconductor layer becomes compositionally-graded through its depth, from substantially intrinsic at the interface with the back surface of the substrate, to substantially conductive at the opposite side.

Generally, the embodiments discussed herein can provide passivation techniques to minimize the negative effects of surface defects, and have a smaller absorption coefficient to minimize wasteful light adsorption in the front of the structure. Particularly, the absorption coefficient of crystalline silicon is generally much smaller than amorphous silicon. Thus, utilizing a crystalline silicon layer can allow more light to be absorbed in the region where it contributes to the cell performance, rather than in the front of the structure. The present invention can also provide a field effect for minimizing the recombination of charge carriers. Particularly, n⁺ or p⁺ diffused regions in cells can effectively keep minority carriers away from the surface. Incorporating such a field in a semiconductor structure can repel minority carriers. Alternatively, a compositionally graded layer may be incorporated into the structure. In addition, the present invention can provide anti-reflective properties to improve the performance of the device. One such exemplary property to improve anti-reflectiveness is texturing. Generally, it is preferred that the front of a semiconductor structure be textured. Therefore, it is desirable for a front layer of a semiconductor structure to have a low absorption, good passivation, and anti-reflection properties.

Various features, aspects, and advantages of this invention will become more apparent from the following detailed description, taken in conjunction with the accompanying drawings.

### BRIEF DESCRIPTION OF THE DRAWINGS

FIG. 1 is a schematic diagram depicting a representative solar module, including a plurality of solar cell devices according to one exemplary embodiment.

FIG. 2 is a schematic cross-section depicting a representative semiconductor structure according to one exemplary embodiment.

FIG. 3 is a schematic cross-section depicting a representative semiconductor structure according to another exemplary embodiment.

FIG. 4 is a schematic cross-section depicting yet another representative semiconductor structure according to still another exemplary embodiment.

FIG. 5 is an exemplary schematic cross-section depicting a representative semiconductor structure according to yet another exemplary embodiment.

FIG. 6 is a schematic cross-section depicting a representative semiconductor structure according to a further exemplary embodiment.

FIG. 7 is a schematic cross-section depicting a representative semiconductor structure according to yet a further exemplary embodiment.

FIG. 8 is a schematic cross-section depicting a representative semiconductor structure according to still a further exemplary embodiment.

### DETAILED DESCRIPTION OF THE INVENTION

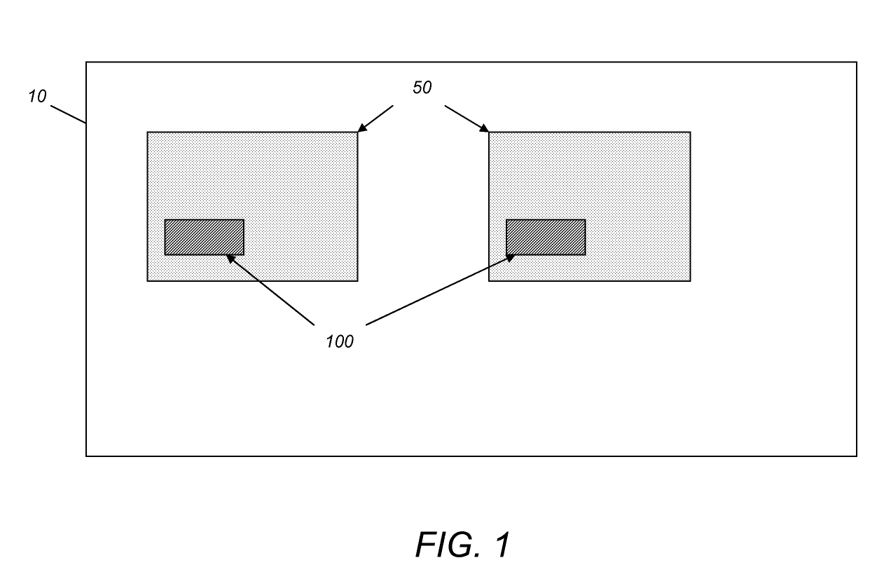

As depicted in FIG. 1, one exemplary embodiment of a solar module 10 can include a plurality of solar cell devices 50. Particularly, each solar cell device 50 may further include at least one or more semiconductor structures 100.

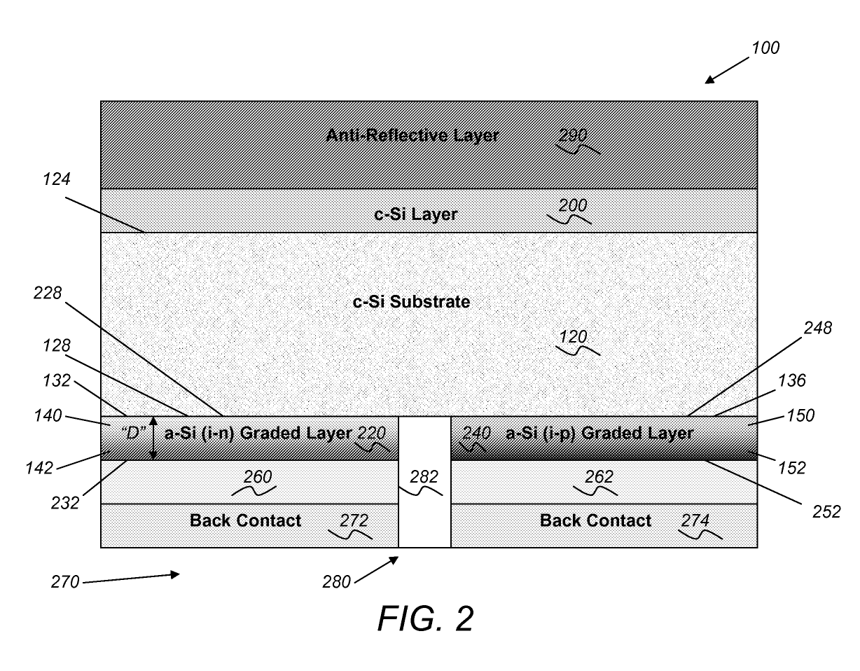

As depicted in FIG. 2, an exemplary semiconductor structure 100 can include a substrate 120, a first semiconductor layer 200, a second semiconductor layer 220, a third semiconductor layer 240, a first electrode layer 260, a second electrode layer 262, at least one electrical contact 270, and a transparent or anti-reflective layer 290. Generally, the substrate 120 can include a front surface 124 and a back surface 128. The substrate 120 usually has a thickness of about 50 microns-about 600 microns. The substrate 120 can be a crystalline silicon, such as a multi-crystalline, including one or more dopants, such as a p-type or an n-type, or a mono-crystalline silicon. Desirably, the substrate 120 is an n-type-mono-crystalline silicon. A multi-crystalline can have large grains, but the width of each grain is typically smaller than the thickness of the substrate 120. As an example, typical sizes for these crystals are about 50 microns wide and about 200 microns thick. Generally, a mono-crystalline layer includes a large, single crystal, but may include more than one crystal as long as each crystal is sufficiently sized so electrons and holes do not experience any grain boundaries within the layer.

In one exemplary embodiment, a first semiconductor layer 200 is formed on the front surface 124 of the substrate 120. The thickness of the first semiconductor layer 200 will depend on various factors, including the optical and electrical characteristics of the layer 200. The thickness of the layer 200 can be influenced by the extent to which recombination of charge carriers at the front surface 124 of the substrate 120 is to be minimized. Usually, the thickness of the layer 200 is less than or equal to about 250 angstroms. In some specific environments, the layer 200 can have a thickness in the range of about 40 angstroms-about 300 angstroms. The most appropriate thickness in a given situation can be determined without undue effort, e.g., by taking measurements related to the photoelectric conversion efficiency of the solar cell module 10 which incorporates the semiconductor structure 100.

Generally, the first semiconductor layer 200 is formed on the front of the semiconductor structure 100 on the semiconductor substrate 120 and can be a crystalline, which may include an epitaxial layer or film, a poly-crystalline, a micro-crystalline, or a nano-crystalline. An epitaxial layer or film can have a crystalline orientation maintained at an interface with the substrate 120 by, e.g., growing ordered crystals on a crystalline substrate. A poly-crystalline can have large grains, such as a multi-crystalline, but generally differs from a multi-crystalline because a poly-crystalline is typically a grown film. As a result, generally the thickness of each poly-crystalline grain is a few microns (about 50 micron wide and about 1.5 micron thick). Generally, a micro-crystalline is a mixed amorphous and crystalline phase with grains that are on the micron scale size (about 0.5- about 5 micron). A nano-crystalline is typically similar to a micro-crystalline, but may have smaller dimensions. Usually, a nano-crystalline is a material having a size range of about 5-about 500 nanometers. Any of these crystal layers can be doped with an n-type or p-type dopant, or be intrinsic. In this exemplary embodiment, the substrate 120 is doped with one or more n-type dopants. The first semiconductor layer 200 can be a crystalline silicon, or specifically a μc—Si:H, μc—SiC:H, or μc—SiGe:H. Moreover, the first semiconductor layer 200 can include a plurality of layers or sub-layers, as described hereinafter. If the first semiconductor layer 200 includes a plurality of layers, each layer can be the same or different type of crystalline. Also, the first semiconductor layer 200 can be “compositionally graded” or include a diffused region, as discussed hereinafter.

Typically, the second semiconductor layer 220 is formed on at least a portion 132 of the back surface 128 of the semiconductor substrate 120. The second semiconductor layer 220 may be compositionally graded throughout its depth as depicted in FIG. 2. The dopant, which can be one or more n-type or p-type dopants, may range in concentration at an interface 228 to an opposite side 232. Preferably, the second semiconductor layer 220 has a low or no concentration of dopants at the interface 228, and a higher concentration of dopants at an opposite side 232. Generally, the one or more dopants are most concentrated at a region 142 near the opposite side 232, and less so at a region 140 near the interface 228.

Generally, the third semiconductor layer 240 is spaced apart from the second semiconductor layer 220 and is formed on another portion 136 of the back surface 128 of the semiconductor substrate 120. Desirably, this layer 240 is also compositionally graded throughout its depth, similarly as the second semiconductor layer 220, with one or more n-type or p-type dopants. Desirably, the third semiconductor layer 240 has a low or no concentration of dopants at an interface 248, which increases at an opposite side 252. Generally, the one or more dopants are most concentrated at a region 152 near the opposite side 252, and less so at a region 150 near the interface 248.

The second semiconductor layer 220 and the third semiconductor layer 240 can be doped with n-type or p-type dopants independent of the dopant of the substrate 120. In this preferred example, the second semiconductor layer 220 is doped with n-type dopants and the third semiconductor layer 240 is doped with p-type dopants. Otherwise, if the second semiconductor 220 is doped with p-type dopants, then the third semiconductor layer 240 is doped with n-type dopants. The second semiconductor layer 220 and the third semiconductor layer 240 can each be a crystalline semiconductor layer, according to any of the specific types as discussed above for the first semiconductor layer 200, or can be amorphous. Generally, the layers 220 and 240 are both amorphous or both crystalline. Preferably, the second semiconductor layer 220 and the third semiconductor layer 240 are amorphous.

The term “compositionally-graded” is meant to describe a change (i.e., a “gradation”) in dopant concentration as a function of the depth (“D”) of, e.g., the second and third semiconductor layers 220 and 240. Although the depth “D” of layers 220 and 240 are depicted as being the same in this exemplary embodiment, it should be understood that the depth of these layers 220 and 240 can be different. In some embodiments, the gradation is substantially continuous, but this does not always have to be the case. For example, the rate-of-change in concentration may itself vary through the depth, increasing slightly in some regions and decreasing slightly in others. However, the overall gradation is always characterized as a decrease in dopant concentration in the direction toward the substrate 120. Moreover, in some instances, the dopant concentration may remain constant for some portion of the depth, although that portion would probably be very small. Any and all of these variations in gradations are meant to be encompassed by the term “graded”. The specific dopant concentration profile for a given semiconductor layer will depend on various factors, e.g., the type of dopant and the electrical requirements for the semiconductor device; as well as its microstructure and thickness. The concept of compositional grading for these types of layers is also generally described in U.S. patent application Ser. No. 11/263,159, filed on Oct. 31, 2005, for J. Johnson and V. Manivannan.

As mentioned above, the dopant concentration for the layer 220 is substantially zero at the interface 228 with the substrate 120, regardless of the particular dopant profile. Thus, an intrinsic region 140 functions to prevent recombination of the charge-carriers at the interface 228 with the substrate surface 128. At the opposite, lower surface of the layer 220, the region 142 is substantially conductive. The specific dopant concentration in that region 142 may depend on the particular requirements for the semiconductor structure 100.

Usually, the regions 142 and 152 have, independently, a concentration of dopant in the range of about 1×10¹⁶ cm⁻³-about 1×10²¹ cm⁻³, preferably about 1×10¹⁹ cm⁻³-about 1×10²¹ cm⁻³. However, the specific concentration of one region 142 to the other 152 does not need to be identical, and can depend, in part, on the overall configuration of the device 50. Moreover, the overall gradation pattern for the second semiconductor layer 220 may be similar or substantially identical to that of the third semiconductor layer 240. However, in some embodiments, the gradation profiles can differ from each other—again depending on factors such as layer composition and thickness, dopant-type, semiconductor requirements, and the like. Moreover, it should be emphasized that the exact depth of “regions” 140, 142, 150 and 152 can vary, depending on factors discussed herein, such as semiconductor layer thickness and dopant profile. The same is true for the analogous regions depicted in the other figures.

The thicknesses of the layers 220 and 240 can also depend on various factors such as the type of dopant employed, the conductivity-type of the substrate, the grading profile, and the dopant concentration in the regions 142 and 152. As in the case of the layer 200, the thicknesses of the layers 220 and 240 are, independently, usually less than or equal to about 250 angstroms. In some specific embodiments, the graded layers 220 and 240 have, independently, a thickness in the range of about 30 angstroms-about 180 angstroms. As described previously for layer 200, the most appropriate thickness in a given situation can readily be determined by taking measurements related to the photoelectric conversion efficiency of the device 50. Measurement of other properties (such as open circuit voltage (Voc), short circuit current (Isc), and fill factor (FF)) can also be helpful in determining the most appropriate thickness for layers 220 and 240.

The first electrode layer 260 and the second electrode layer 262 may be formed over, respectively, the second semiconductor layer 220 and the third semiconductor layer 240. However, these layers 260 and 262 are optional. In some preferred embodiments (although not all), an electrode layer 260 and/or 262 are formed on the backside of, respectively, the layers 220 and 240 (FIG. 2). Usually, the electrode layer 260 or 262 functions as a diffusion barrier layer, preventing metal atoms from diffusing from a conductive layer (described below) into, respectively, the semiconductor layer 220 or 240. Generally, it is preferred that the electrode layers 260 and 262 are a transparent conductive oxide. Typically, the electrode layer 260 or 262 is formed from a conductive material such as indium tin oxide, ZnO, doped ZnO, and the like. An exemplary transparent conductive oxide (TCO) is indium tin oxide (ITO). The layers 260 and 262 can be formed from any of the typical deposition techniques used to deposit conductive layers. Each layer 260 and 262 usually has a thickness in the range of about 50 angstroms-about 500 angstroms, although this range may vary considerably. Although the electrode layers 260 and 262 are optional, it is generally desirable to have an electrical contact to both the n-region and p-region on the back surface of the substrate.

In addition, at least one electrical contact 270, which includes a first back or electrical contact 272 and a second back or electrical contact 274, can be formed over, respectively, the optional first electrode layer 260 and the second electrode layer 262, or if not present, over the second semiconductor layer 220 and the third semiconductor layer 240. Generally, the first back contact 272 is a positive side and the second back contact 274 is a negative side, or vice-versa. The at least one electrical contact 270 can function as a conducting electrode, conveying the electric current generated by the module 10 to a desired location. The at least one contact 270 may be formed of a variety of conductive materials, such as silver (Ag), aluminum (Al), copper (Cu), molybdenum (Mo), tungsten (W), titanium (Ti), palladium (Pd), and various combinations thereof. Although each of the first and second contacts 272 and 274 are illustrated as a layer of material in FIG. 2, their respective shape and size can vary considerably. Each electrical contact 272 and 274 can be formed by various techniques, e.g., plasma deposition, screen-printing, vacuum evaporation (sometimes using a mask), pneumatic dispensing, or direct-write techniques such as ink jet printing.

Desirably, an isolation trench 280 is formed by the spaced apart third semiconductor layer 240 and the second semiconductor layer 220, along with the electrode layers 260 and 262 and the at least one electrical contact 270. Typically, the primary function of the trench 280 is to electrically and structurally isolate the two semiconductor layers 220 and 240, and/or to isolate the contact 272 from the contact 274. The precise shape of the trench 280 can also vary. The trench 280 can be formed by a number of conventional techniques—either during or after the fabrication of the various semiconductor and contact layers. As an example, the trench 280 could be formed by drilling processes such as laser drilling, or by mechanical scribing techniques. In some instances, the trench 280 is filled or partially filled with an electrically-insulating material 282, e.g., a polymeric resin or SiO₂. The insulating material may serve to protect the underside of the substrate 120 during various fabrication steps used to form the device, such as etching, milling, or scribing steps.

The metal contacts 272 and 274 can constitute a portion of an electrical system for interconnecting the various semiconductor elements. Any conventional electrical design may be used for such a system. As emphasized herein, preferred embodiments have all the electrical contacts incorporated into locations ensuring that the front surface of the structure 100, i.e., the top surface of the layer 290, is substantially free of any features that would obstruct incoming light. Typically, the various electrical interconnections are located in the general vicinity of substrate back surface 128, forming an “all-back-contact” configuration.

As one illustration, the contacts 272 and 274 may be interdigitated. As an example (and when viewed from a planar perspective for the device), the contacts 272 and 274 may be arranged in a comb-shape, as described in U.S. Publication 2005/0062041 A1 (Terakawa et al.). Interdigitated arrangements are also described in various other references, e.g., U.S. Pat. No. 5,053,083 (Sinton); U.S. Pat. No. 4,200,472 (Chappell et al.); and Publication 2004/0200520 A1 (Mulligan et al.). Those skilled in the art will be able to readily determine the most appropriate metallization and electrical scheme for a particular device, without undue effort.

Furthermore, the semiconductor structure 100 can also include a transparent or anti-reflective layer 290. According to this exemplary embodiment, the layer 290 is disposed on the first semiconductor layer 200 on the light-receiving side of the device 50, such as a photovoltaic device. The layer 290 can provide anti-reflective (AR) characteristics for the semiconductor structure 100, and may include a variety of materials, such as metal oxides. Non-limiting examples include silicon oxide (SiO₂), silicon nitride (SiN), zinc oxide (ZnO), doped ZnO, and indium tin oxide (ITO). The layer 290 can be formed by various conventional techniques, such as sputtering or evaporation. Its thickness will depend on various factors, including desired AR characteristics. Usually, the layer 290 can have a thickness in the range of about 200 angstroms-about 1000 angstroms.

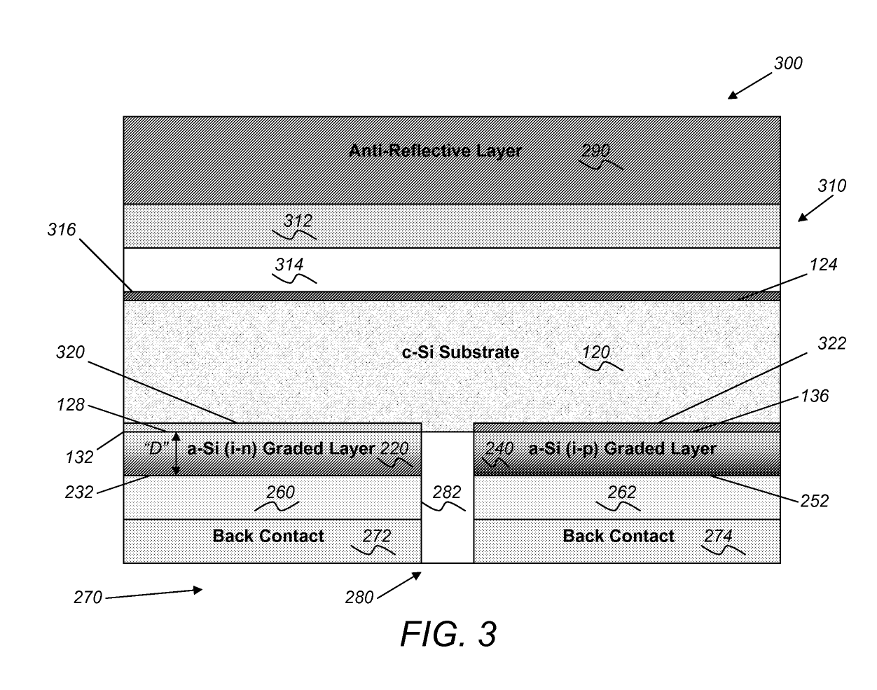

Furthermore, the semiconductor structure 100 may include a first back surface interface 320 and a second back surface interface 322, as depicted in FIG. 3, as hereinafter described.

Another exemplary embodiment of a semiconductor structure 300 is depicted in FIG. 3. (In this figure and hereinafter, many of the elements similar or identical to an earlier figure may not be labeled, or may be provided with the same element numerals as an earlier figure). The semiconductor structure 300 includes a substrate 120, a first semiconductor layer 310, a second semiconductor layer 220, a third semiconductor layer 240, a first electrode layer 260, a second electrode layer 262, at least one electrical contact 270, and a transparent or an anti-reflective layer 290. The substrate 120, the second semiconductor layer 220, the third semiconductor layer 240, the first electrode layer 260, the second electrode layer 262, at least one electrical contact 270, and the anti-reflective layer 290, are substantially similar as those described above.

The first semiconductor layer 310 can include a plurality of layers or sub-layers 312 and 314. The first sub-layer 312 can be an n⁺ epitaxial layer and the second sub-layer 314 can be an epitaxial layer. Optionally, a front surface interface 316 of the substrate can be doped. Exemplary dopants can be n-type or p-type dopants. Generally the type of dopants used is similar to that of the substrate 120. Moreover, the dopants are at a higher concentration than that of the substrate 120. As an example, if the substrate 120 has an n-type dopant, then the interface would be doped with a higher concentration of n⁺ dopant, and still a higher concentration of dopant in the layer 312. Usually, the sum of thicknesses of the sub-layers 312 and 314 is less than or equal to about 250 angstroms. In some specific environments, the sum of the sub-layers 312 and 314 can have a thickness in the range of about 30 angstroms-about 300 angstroms. Moreover, the thickness of the sub-layers 312 and 314 can be the same or different. The most appropriate thickness in a given situation can be determined without undue effort, e.g., by taking measurements related to the photoelectric conversion efficiency of the solar cell module 10 which incorporates the semiconductor structure 300.

In addition, the substrate 120 can be doped at the first back surface interface 320 and second back surface interface 322. Generally, the first back surface interface 320 is doped with a similar dopant as the second semiconductor layer 220, and the second back surface interface 322 is doped with a similar dopant as the third semiconductor layer 240. In this exemplary embodiment as depicted in FIG. 3, the second semiconductor layer 220 is compositionally graded with n-dopants. Thus, the first back surface interface 320 is also doped with n-type dopants. In addition, the third semiconductor layer 240 is compositionally graded with p-type dopants, so the second back surface interface 322 is also doped with p-type dopants.

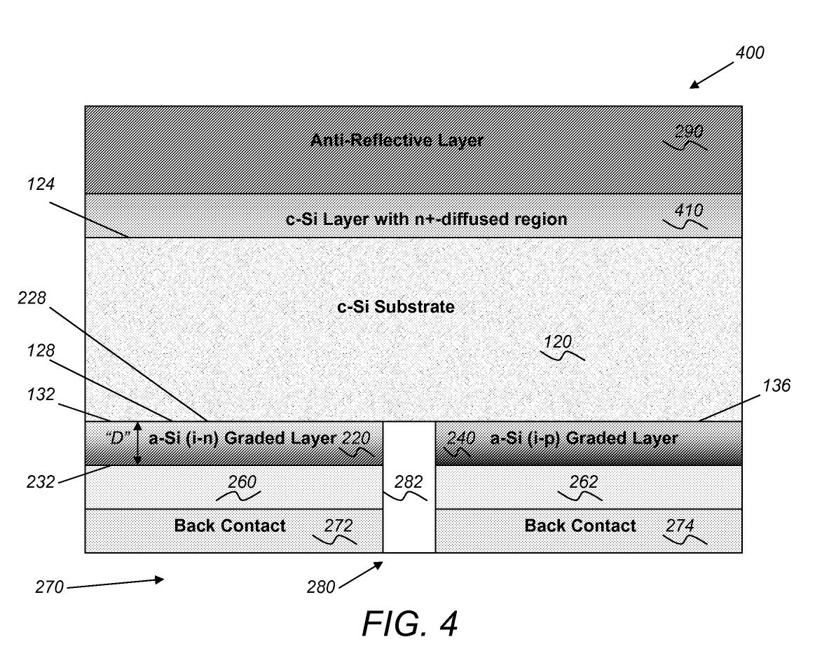

A further embodiment of the present invention is depicted in FIG. 4. A semiconductor structure 400 is substantially similar to the semiconductor structure 100, except the first semiconductor layer 200 has been replaced with a first semiconductor layer 410. In this exemplary embodiment, the first semiconductor layer 410 includes a crystalline silicon with an n⁺-diffused region. Alternatively, the layer 410 can be a part of the substrate 120 and be an n⁺-diffused region in the substrate 120. Generally, the first semiconductor layer 410 has the same type of dopants as the substrate 120. In this instance, the substrate has one or more n-type dopants, so the layer 410 includes an n⁺-diffused region. On the other hand, if the substrate 120 is a p-type substrate, then the first semiconductor layer 410 can have a p⁺-diffused region.

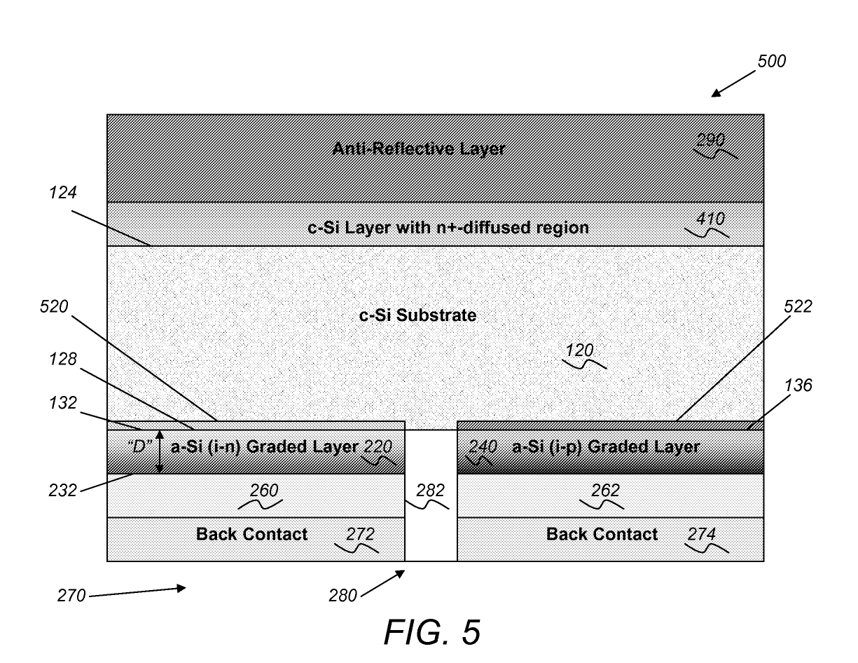

Yet another exemplary embodiment is depicted in FIG. 5. A semiconductor structure 500 is substantially similar to the semiconductor structure 400, except the semiconductor structure 500 also includes a first back surface interface 520 and a second back surface interface 522. Generally, the interfaces 520 and 522 are doped with, respectively, an n-type or p-type dopant, corresponding to the dopants in the compositionally graded layers 220 and 240. In this exemplary embodiment, the second semiconductor layer 220 is compositionally graded with n-type dopants, and the third semiconductor layer 240 is compositionally graded with p-type dopants. Consequently, the first interface 520 is doped with n-type dopants and the second interface 522 is doped with p-type dopants.

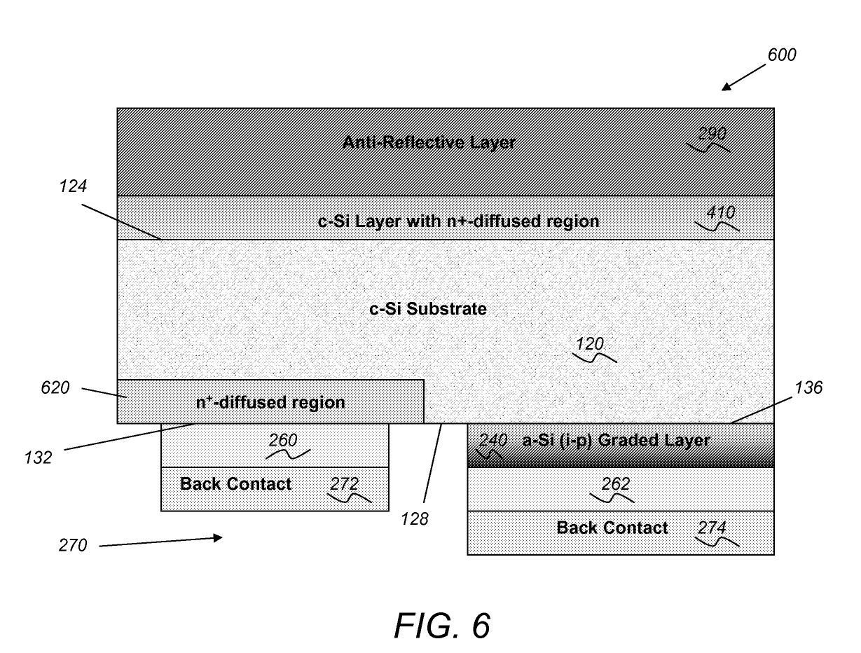

A still further exemplary embodiment of the present invention is depicted in FIG. 6. An exemplary semiconductor structure 600 is substantially similar to the semiconductor structure 400. However, instead of having a compositionally graded layer or second semiconductor layer 220, an n⁺-diffused region 620 is created on the crystalline silicon substrate 120, substantially near the back surface 128 of the portion 132. The concentration of dopant can be similar to that of the region 142 of the structure 100, as long as it exceeds the concentration of n-type dopant in the crystalline substrate 120 and acts to reflect/repel charge carriers of the other type and attract the other charge carrier to prevent premature recombination.

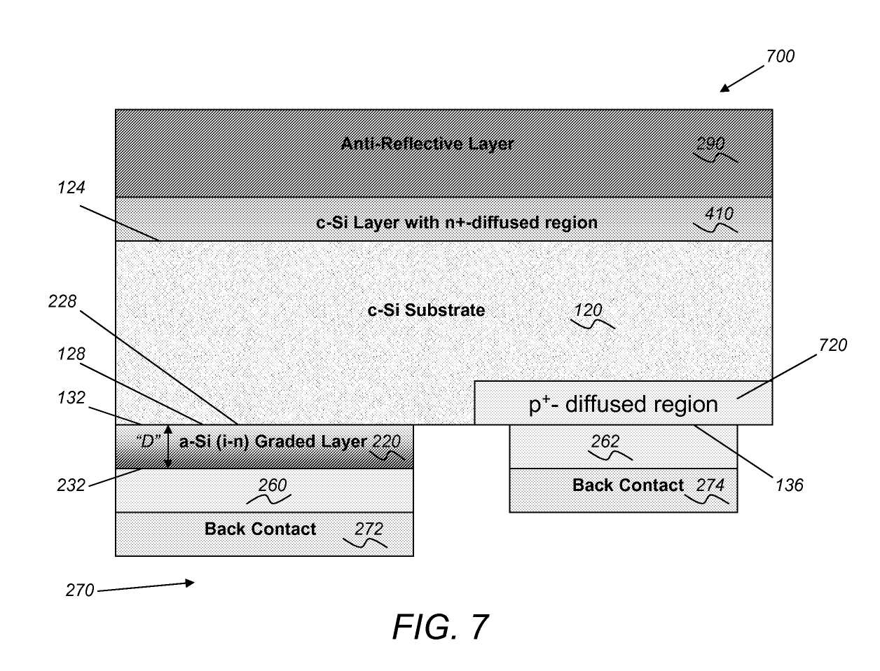

Referring to FIG. 7, still yet another embodiment is depicted. In this exemplary embodiment, a semiconductor structure 700 is also substantially similar to the semiconductor structure 400. However, the compositionally graded layer 240, having p-type dopants is replaced with a p⁺-diffused region 720 on the crystalline substrate 120 substantially near the back surface 128 of the another portion 136. The concentration of dopant can be similar to that of the region 152 of the structure 100, as long as it exceeds the concentration of p-type dopant in the crystalline substrate 120 and acts to attract holes and reflect/repel electrons to prevent premature recombination.

Generally, the structures having one or more crystalline layers discussed above do not absorb more than about 2 mA/cm² of light in a passivation layer. Furthermore, the anti-reflection properties can be obtained by texturing the surface as discussed hereinafter, such that the reflection is typically less than 5% over the relevant spectrum. Regarding passivation, typical defect density values are between about 1×10¹⁰-about 1×10¹² cm⁻². Desirably, the passivation values do not exceed about 1×10¹¹ cm⁻².

A variety of conventional treatment steps are usually carried out on the substrate 120, prior to deposition of the other semiconductor layers. For example, the substrate 120 can be cleaned and placed in a vacuum chamber, e.g., a plasma reaction chamber. The chamber can then be heated to temperatures sufficient to remove any moisture on or within the substrate 120. Usually, a temperature in the range of about 120- about 240° C. is sufficient. Sometimes, hydrogen gas is then introduced into the chamber, and the substrate 120 is exposed to a plasma discharge for additional surface-cleaning and passivation. However, many variations on cleaning and pretreatment steps are possible. Usually, these steps are carried out in the chamber used for additional fabrication of the device.

The various semiconductor layers formed over the substrate 120 are usually (though not always) applied by plasma deposition. Many different types of plasma deposition are possible. Non-limiting examples include chemical vapor deposition (CVD), vacuum plasma spray (VPS), low pressure plasma spray (LPPS), plasma-enhanced chemical-vapor deposition (PECVD), radio-frequency plasma-enhanced chemical-vapor deposition (RFPECVD), expanding thermal-plasma chemical-vapor deposition (ETPCVD), electron-cyclotron-resonance plasma-enhanced chemical-vapor deposition (ECRPECVD), inductively coupled plasma-enhanced chemical-vapor deposition (ICPECVD), and air plasma spray (APS). Sputtering techniques can also be used, e.g., reactive sputtering. Moreover, combinations of any of these techniques might also be employed. Those skilled in the art are familiar with the general operating details for all of these deposition techniques. In some preferred embodiments, the various semiconductor layers are formed by a PECVD or CVD process. An exemplary CVD process is disclosed in U.S. Pat. No. 7,075,052 B2 (Shima et al.).

The semiconductor structures depicted above can be made by methods known to those of skill in the art. Particularly, the method of making various crystalline layers can be accomplished by chemical vapor deposition (CVD). Such methods are provided in, e.g., U.S. Pat. No. 7,075,052 B2 (Shima et al.). Moreover, creating diffused dopant regions in substrates is also known to those who are skilled in the art. Such diffused regions can be created by low pressure chemical vapor deposition (LPCVD) followed by a high temperature step, as disclosed by, e.g., U.S. Pat. No. 6,110,772 (Takada et al.), or by standard high temperature diffusion techniques at temperatures at about 900° C.

The compositional-grading of semiconductor layers 200, 220 and 240 as depicted in, e.g., FIG. 1 can be carried out by various techniques. The deposition of each layer is typically undertaken in separate steps. Usually, grading is accomplished by adjusting the dopant levels during plasma deposition. In a typical embodiment, a silicon precursor gas such as silane (SiH₄) is introduced into the vacuum chamber in which the substrate is situated. A diluting gas such as hydrogen may also be introduced with the silicon precursor gas. Flow rates for the precursor gas can vary considerably, and depend largely on the size of the chamber and the pump-capacity. During the initial stages of deposition, no dopant precursors are present. Therefore, regions 140 and 150 are substantially intrinsic (“undoped”), as mentioned above, serving to passivate the surface of substrate 120.

As an example, the deposition process continues for each of the layers 220 and 240, as a dopant precursor is added to the plasma mixture. Choice of a precursor will of course depend on the selected dopant. An n-type dopant such as a Group V element, e.g., phosphorus (P), arsenic (As), or antimony (Sb); or a p-type dopant such as a Group III element, e.g., boron (B) may be utilized. A vehicle, such as diborane gas (B₂H₆) for the p-type dopant or phosphine (PH₃) for the n-type dopant, can deliver the selected dopant. The vehicle gases may be in pure form, or they may be diluted with a carrier gas, such as argon, hydrogen, or helium.

During the formation of each layer 220 and 240, the addition of the dopant gas is carefully controlled to provide the desired doping profile. Those skilled in the art are familiar with gas metering equipment, e.g., mass flow controllers, which can be used to carry out this task. The feed rate for the dopant gas will be selected to substantially match the gradation scheme described above. Thus, in very general terms, the feed rate of the dopant gas will gradually increase during the deposition process. However, many specific changes in feed rate can be programmed into the deposition scheme. Maximum flow rates at the conclusion of this step of the process result in the formation of substantially-conductive regions 142 and 152, as mentioned previously. Each of regions 142 and 152 can form a heterojunction with the substrate 120.

In addition, one or more diffused regions can be formed over the front or back surface 124 and 128 of the substrate 120. The diffused regions can contain n-type or p-type dopants, and may exceed the dopant concentration in the substrate 120. Exemplary methods for diffusing dopants are disclosed in U.S. Pat. No. 6,110,772 (Takada et al.).

In some preferred embodiments of the present invention, at least one of the planar surfaces of the semiconductor device is textured. Texturing of the various surfaces of the device can reduce undesirable light reflection. Moreover, texturing can utilize incoming light much more effectively, by elongating an optical path length in one of the semiconductor layers (“optical light trapping”). Usually, at least the front-side (i.e., the surface closest to incident light) is textured.

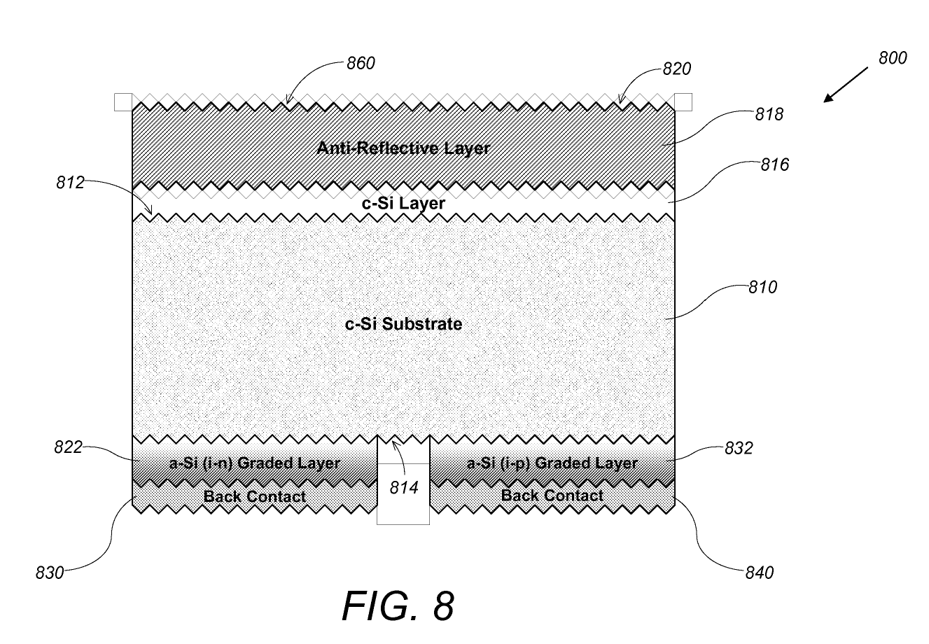

Referring to FIG. 8, a non-limiting illustration of a semiconductor structure 800 is depicted. Except for texturing, the semiconductor structure 800 is substantially similar to the semiconductor structure 100 as depicted in FIG. 2. In some preferred embodiments, the front surface 812 of the substrate 810 is textured, as shown in FIG. 8. Moreover, a back surface 814 can be textured.

The type of texturing can vary considerably, depending on a number of factors discussed previously. As one example, textured features can be in the form of microscopic pyramids 860, as shown in FIG. 8. It should be emphasized that FIG. 8 happens to show all planar surfaces as being textured, although there is no requirement or preference for that to be the case. As those skilled in the art understand, the textured profile for many of the surfaces can effectively result from the profile of the underlying surfaces. For example, if substrate surfaces 812 and 814 are textured, layers deposited over those surfaces (and layers thereafter) will often adapt the conformal features of the substrate surfaces. This is depicted in FIG. 8 for semiconductor layers 816, 822, and 832; a transparent or anti-reflective layer 818 with a top surface 820; and electrical or metallic contacts 830 and 840. (The optional electrode layers, e.g., layers 260 and 262 in FIG. 2, can also be textured, when present).

Texturing can be carried out by a variety of techniques. One instructive source of information is an article by David King et al., “Experimental Optimization of an Anisotropic Etching Process for Random Texturization of Silicon Solar Cells”, IEEE Conference Proceedings (1991), pages 303-308. Very often, texturing can be carried out by etching techniques, using mild alkaline solutions with low concentrations (e.g., less than about 5% by volume) of basic compounds like potassium hydroxide or sodium hydroxide. The alkaline solutions can contain other components as well, e.g., hydroxy compounds such as isopropyl alcohol. Many other types of alkaline solutions may also be employed.

Various other details regarding the texturing of semiconductor layers for photovoltaic devices are known in the art. As one example, U.S. Pat. No. 6,670,542 (Sakata et al.) describes steps in forming textured surfaces for single crystalline layers used in photovoltaic conversion devices.

The discussion above relates to semiconductor structures which are often used as solar cell devices. One or more of these devices can be incorporated into the form of a solar module. For example, a number of the solar cell devices can be electrically connected to each other, in series or in parallel, to form the module. (Those of ordinary skill in the art are familiar with details regarding the electrical connections, etc). Such a module is capable of much greater energy output than the individual solar cell devices.

Non-limiting examples of solar modules are described in various references, e.g., U.S. Pat. No. 6,667,434 (Morizane et al.). The modules can be formed by various techniques. For example, a number of solar cell devices can be sandwiched between glass layers, or between a glass layer and a transparent resin sheet, e.g., those made from EVA (ethylene vinyl acetate). The use of the graded layers can improve device properties like photoelectric conversion efficiency, etc., and thereby improve the overall performance of the solar module.

U.S. Pat. No. 6,667,434 (Morizane et al.) also describes various other features for some of the solar modules. For example, the patent describes “two-side incidence”-type solar modules in which light can contact both front and rear surfaces of the module. Moreover, the patent describes solar modules which must be extremely moisture-proof (e.g., those used outdoors). In these types of modules, sealing resins can be used to seal the side of each solar cell element. Furthermore, the modules may include various resinous layers which prevent the undesirable diffusion of sodium from nearby glass layers. All of these types of solar modules may incorporate devices which comprise the compositionally-graded layer (or layers) described herein.

Those skilled in the art are generally familiar with many other details regarding the primary components of the solar modules, e.g., the various substrate materials, backing materials, and module frames. Other details and considerations are also well-known, e.g., wire connections in and out of the module (for example, those leading to an electrical inverter); as well as various module encapsulation techniques.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed:

1. A semiconductor structure, comprising:
(a) a semiconductor substrate of one conductivity type, having a front surface and a back surface;
(b) a first semiconductor layer disposed on the front surface of the semiconductor substrate;
(c) a second semiconductor layer disposed on a portion of the back surface of the semiconductor substrate, wherein the second semiconductor layer is compositionally graded through its depth, from substantially intrinsic at an interface with the substrate, to substantially conductive at an opposite side, the second semiconductor layer having a selected conductivity type obtained by the incorporation of one or more selected dopants; and
(d) a third semiconductor layer disposed on another portion of the back surface of the semiconductor substrate, and spaced from the second semiconductor layer, wherein the third semiconductor layer is compositionally graded through its depth, from substantially intrinsic at an interface with the substrate, to substantially conductive at an opposite side, the third semiconductor layer having a conductivity type different from that of the second layer, and obtained by the incorporation of one or more selected dopants.

2. The semiconductor structure of claim 1, wherein the first semiconductor layer comprises a crystalline layer.

3. The semiconductor structure of claim 2, wherein the crystalline layer comprises a plurality of same or different crystalline layers.

4. The semiconductor structure of claim 2, wherein the crystalline layer comprises a nano-crystalline, a micro-crystalline, a poly-crystalline, an epitaxial layer, or a combination thereof.

5. The semiconductor structure of claim 4, wherein the semiconductor substrate is an n-type substrate and the epitaxial layer is an n⁺ epitaxial layer or the semiconductor substrate is a p-type substrate and the epitaxial layer is an p⁺ epitaxial layer.

6. The semiconductor structure of claim 2, wherein the semiconductor substrate comprises an n-type mono-crystalline material or multi-crystalline material.

7. The semiconductor structure of claim 1, further comprising an intrinsic layer between the first semiconductor layer and the semiconductor substrate, wherein the intrinsic layer and the semiconductor layer are both crystalline.

8. The semiconductor structure of claim 7, wherein an interface between the intrinsic layer and the semiconductor substrate comprises a selected n-type or p-type dopant.

9. The semiconductor structure of claim 1, wherein the first semiconductor layer optionally comprises more than one layer, and each layer, independently, comprises:
μc—Si:H, μc—SiC:H, μc—SiGe:H, or a combination thereof.

10. The semiconductor structure of claim 1, wherein the first semiconductor layer is compositionally graded through its depth with one or more selected dopants, or comprises a diffused n⁺ or p⁺ region.

11. The semiconductor structure of claim 1, wherein for the second semiconductor layer, the third semiconductor layer, or both the second semiconductor layer and the third semiconductor layer, the concentration of one or more dopants at the interface with the substrate is substantially zero; and the concentration of one or more dopants at the opposite side is in the range of about 1×10¹⁹ cm⁻³-about 1×10²¹ cm⁻³.

12. The semiconductor structure of claim 1, wherein a first electrode layer is disposed on the second semiconductor layer and at least one electrical contact is disposed over the first electrode layer, or a second electrode layer is disposed on the third semiconductor layer and at least one electrical contact is disposed on the second electrode layer.

13. The semiconductor structure of claim 1, wherein the second semiconductor layer is spaced from the third semiconductor layer by an isolation trench containing an electrically-insulating material comprising SiO₂.

14. The semiconductor structure of claim 1, wherein each of the second and third semiconductor layers comprises an n-type or a p-type dopant which provides a selected conductivity.

15. The semiconductor structure of claim 14, wherein the first semiconductor layer is intrinsic.

16. The semiconductor structure of claim 1, wherein at least one of the front surface and/or the back surface of the substrate is textured.

17. The semiconductor structure of claim 1, further comprising a transparent layer, wherein the first semiconductor layer is in contact with the transparent layer and both are textured.

18. The semiconductor structure of claim 1, wherein the second semiconductor layer and the third semiconductor layer are substantially amorphous and, independently, compositionally graded with a selected n-type or p-type dopant.

19. The semiconductor structure of claim 18, wherein the semiconductor substrate comprises, independently, a selected n-type or p-type dopant at each interface with the second semiconductor layer and the third semiconductor layer.

20. The semiconductor structure of claim 19, wherein the first semiconductor layer comprises an n⁺-diffused region;
the second semiconductor layer comprises an amorphous silicon compositionally graded with one or more selected n-type dopants and the semiconductor substrate at a first interface with the second semiconductor layer comprises one or more selected n-type dopants; and
the third semiconductor layer comprises an amorphous silicon compositionally graded with one or more selected p-type dopants; and
the semiconductor substrate at a second interface with the third semiconductor layer comprises one or more selected p-type dopants.

21. A semiconductor structure, comprising:
(a) a semiconductor substrate having a front surface and a back surface;
(b) a first semiconductor layer disposed on the front surface of the semiconductor substrate; and
(c) a second semiconductor layer, disposed on at least a portion of the back surface of the semiconductor substrate, and compositionally graded through its depth with one or more selected dopants.

22. A semiconductor structure, comprising:
(a) a semiconductor substrate, having a front surface and a back surface wherein the semiconductor substrate comprises a diffused region proximate to at least a portion of its back surface; and
(b) a semiconductor layer disposed on another portion of the back surface of the semiconductor substrate, wherein the semiconductor layer is compositionally graded through its depth by the incorporation of one or more selected dopants.

23. A semiconductor structure according to claim 22, wherein the semiconductor substrate comprises an n-type substrate, the diffused region is a diffused n⁺ or p⁺ region on at least the portion of the back surface of the semiconductor substrate; and the one or more selected dopants comprises n-type or p-type dopants.

24. A semiconductor structure according to claim 22, wherein the diffused region of the semiconductor substrate is an n⁺ region and the semiconductor layer is compositionally graded with one or more selected p-type dopants, or the diffused region of the semiconductor substrate is a p⁺ region and the second semiconductor layer is compositionally graded with one or more selected n-type dopants.

25. A solar module, comprising one or more solar cell devices, wherein at least one of the solar cell devices comprises:
(a) a semiconductor substrate of one conductivity type, having a front surface and a back surface;
(b) a first semiconductor layer disposed on the front surface of the semiconductor substrate;
(c) a second semiconductor layer disposed on a portion of the back surface of the semiconductor substrate, wherein the second amorphous semiconductor layer is compositionally graded through its depth with one or more selected dopants, the second semiconductor layer having a selected conductivity type; and
(d) a third semiconductor layer disposed on another portion of the back surface of the semiconductor substrate, and spaced from the second semiconductor layer, wherein the third semiconductor layer is compositionally graded through its depth with one or more selected dopants, the third semiconductor layer having a conductivity type different from that of the second layer.

26. The solar module of claim 25, wherein the first semiconductor layer is compositionally graded through its depth with one or more selected dopants, from substantially intrinsic at the interface with the substrate, to substantially conductive at the opposite side.

27. The solar module of claim 26, wherein the first semiconductor layer comprises a diffused region.

28. The solar module of claim 27, wherein the diffused region is an n⁺ or p⁺ diffused region.

29. A method for making a photovoltaic device, comprising:
(I) forming a first semiconductor layer over a front surface of a semiconductor substrate;
(II) forming a second semiconductor layer on a portion of a back surface of the semiconductor substrate, by depositing semiconductor material and a dopant over the back surface portion, while altering a concentration of the dopant, so that the second semiconductor layer becomes compositionally-graded through its depth, from substantially intrinsic at the interface with the back surface of the substrate, to substantially conductive at the opposite side; and
(III) forming a third semiconductor layer on another portion of the back surface of the semiconductor substrate, by depositing semiconductor material and a dopant over the back surface portion, while altering a concentration of the dopant, so that the third semiconductor layer becomes compositionally-graded through its depth, from substantially intrinsic at the interface with the back surface of the substrate, to substantially conductive at the opposite side.

30. The method of claim 29, further comprising diffusing a selected dopant into the semiconductor substrate or the first semiconductor layer formed by deposition.

31. The method of claim 29, further comprising:
(IV) forming a transparent layer over the surface of the first semiconductor layer; and
(V) forming at least one electrical contact over the second amorphous semiconductor layer, and forming at least one electrical contact over the third amorphous semiconductor layer.

32. The method of claim 29, further comprising texturing the front surface of the substrate or the back surface of the substrate; or both the front and back surfaces of the substrate.
